(19) United States
(12) Patent Application Publication
(10) Pub. No.: US 2007/0262470 A1
(43) Pub. Date: Nov. 15, 2007

(54) Module With Built-In Semiconductor And Method For Manufacturing The Module

(75) Inventors: Takashi Ichiryu, Osaka (JP); Yoshihisa Yamashita, Kyoto (JP); Seiichi Nakatani, Osaka (JP)

Correspondence Address: HAMRE, SCHUMANN, MUELLER & LARSON P.C., P.O. BOX 2902-0902, MINNEAPOLIS, MN, 55402, US

(73) Assignee: Matsushita Electric Industrial Co., Ltd., Kadoma-shi, Osaka (JP)

(21) Appl. No.: 11/577,346

(22) PCT Filed: Sep. 20, 2005
(86) PCT No.: PCT/JP05/17282

§ 371 Date: Apr. 16, 2007

(30) Foreign Application Priority Data
Oct. 21, 2004 (JP) 2004-307236

(51) Int. Cl. H01L 23/48; H01L 21/00; H01L 25/00

(52) U.S. Cl. 257/783; 438/108; 257/E25.001; 257/E23.01; 257/E21.001

(57) ABSTRACT

The present invention provides a module with a built-in semiconductor that can suppress a reduction in yield caused by a crack or failure of a semiconductor device in the process of mounting a thin semiconductor device on a wiring board and a method for manufacturing the module. In the module with a built-in semiconductor, a semiconductor device (107) is contained in an interlayer connection member (105) located between a first wiring board (101) and a second wiring board (103). The back side of the semiconductor device (107) is die-bonded to the first wiring board (101) via an adhesive (108), and the semiconductor device (107) is connected electrically to the second wiring pattern (104) via a protruding electrode (109).

### TECHNICAL FIELD

The present invention relates to a module with a built-in semiconductor containing a semiconductor device and a method for manufacturing the module.

### BACKGROUND ART

In recent years, with a demand for compact high-performance electronic equipment, a semiconductor module containing a semiconductor device increasingly has been required to have a higher density and higher performance. General methods for manufacturing such a semiconductor module include, e.g., a method in which a molded semiconductor device package is mounted on a supporting substrate by soldering, wire-bonding mounting in which a semiconductor device (bare chip) is fixed on a supporting substrate and connected electrically with wires, and flip-chip mounting in which a semiconductor device (bare chip) having a protruding electrode is mounted directly on a supporting substrate.

To achieve even higher density, however, a multilevel semiconductor module has been proposed, e.g., by Patent Document 1. In the multilevel semiconductor module, semiconductor devices are mounted on a plurality of wiring boards by the above wire-bonding mounting or flip -chip mounting, and these wiring boards are stacked in multiple levels.

Moreover, a buried-type semiconductor module including a semiconductor device that is buried in an insulating layer of a multilayer wiring board also has been proposed, e.g., by Patent Documents 2 and 3.

Further, Patent Document 4 has proposed a method in which a semiconductor device is contained face-up in an insulating layer and then connected electrically to a wiring board. Patent Document 5 has proposed a method for producing a multilevel semiconductor module in which semiconductor modules obtained by the method disclosed in Patent Document 4 are stacked in multiple levels.

Patent Document 1: JP 2001-35997 A

Patent Document 2: JP 11(1999)-45955 A

Patent Document 3: JP 2003-174141 A

Patent Document 4: JP 2003-188314 A

Patent Document 5: JP 2003-218319 A

With the above conventional techniques, the semiconductor device and the wiring board can be connected electrically. However, small thin equipment such as a mobile personal computer or personal digital assistant typified by a portable telephone will be needed more and more in the future. A typical example of the equipment may be a card-size personal digital assistant. The card-size personal digital assistant is expected to extend its application to card-size wireless equipment, a portable telephone, a personal identification/authentication card, or the like. To meet the future needs, the semiconductor module should be even smaller and thinner.

In order to reduce the size and thickness of the semiconductor module, a thin semiconductor device (e.g., with a thickness of 100 μm or less) in which the opposite side (referred to as the back side in the following) to the circuit surface of the semiconductor device is polished may be used. However, such a thin semiconductor device suffers many cracks etc. during the operations of transporting the semiconductor device for flip-chip mounting, aligning the semiconductor device with the wiring boards, or making connection between the semiconductor device and the wiring boards, so that the handling properties may become poor. Therefore, the thin semiconductor device (particularly a silicon semiconductor) has low mechanical strength and is likely to be damaged when transported or connected.

### DISCLOSURE OF INVENTION

To solve the above problems, it is a main object of the present invention to provide a module with a built-in semiconductor that can suppress a reduction in yield caused by a crack or failure of a semiconductor device in the process of mounting a thin semiconductor device on a wiring board, and a method for manufacturing the module.

A module with a built-in semiconductor of the present invention includes the following: a first wiring board; a second wiring board; an interlayer connection member having electrical insulation properties that is located between the first wiring board and the second wiring board; and a semiconductor device contained in the interlayer connection member. The first wiring board includes a first wiring pattern formed on both principal surfaces. The second wiring board includes a second wiring pattern formed on both principal surfaces. The first wiring pattern and the second wiring pattern are connected electrically by a via conductor passing through the interlayer connection member. The back side of the semiconductor device is die-bonded to the first wiring board via an adhesive, and a first electrode pad provided in the circuit surface of the semiconductor device is connected electrically to the second wiring pattern via a protruding electrode.

A method for manufacturing a module with a built-in semiconductor of the present invention produces a module with a built-in semiconductor containing a semiconductor device. The method includes the following steps of: a) die-bonding the back side of the semiconductor device to a desired position of a first wiring board via an adhesive; b) forming a protruding electrode on a first electrode pad provided in the circuit surface of the semiconductor device so as to be connected electrically to a second wiring pattern formed on a second wiring board; c) forming a through hole in an interlayer connection member in the uncured state and filling the through hole with a conductive paste; d) aligning and stacking the first wiring board, the interlayer connection member, and the second wiring board so that the semiconductor device is flip-chip mounted on the second wiring pattern, and the through hole is arranged between a first wiring pattern formed on the first wiring board and the second wiring pattern; and e) heating and pressing the first wiring board, the interlayer connection member, and the second wiring board thus stacked so that the semiconductor device is contained in the interlayer connection member, the first wiring board, the interlayer connection member, and the second wiring board are cured and formed integrally, and the first wiring pattern and the second wiring pattern are connected electrically by a via conductor formed in the through hole.

### BRIEF DESCRIPTION OF DRAWINGS

FIG. 1 is a cross-sectional view showing a module with a built-in semiconductor in Embodiment 1 of the present invention.

FIG. 2 is a cross-sectional view showing a modified module with a built-in semiconductor in Embodiment 1 of the present invention.

FIGS. 3A to 3E are cross-sectional views showing each process of a method for manufacturing a module with a built-in semiconductor in Embodiment 1 of the present invention.

FIG. 4 is a cross-sectional view showing a module with a built-in semiconductor in Embodiment 2 of the present invention.

FIGS. 5A to 5F are cross-sectional views showing each process of a method for manufacturing a module with a built-in semiconductor in Embodiment 2 of the present invention.

FIGS. 6A to 6F are cross-sectional views showing each process of another method for manufacturing a module with a built-in semiconductor in Embodiment 2 of the present invention.

FIG. 7 is a cross-sectional view showing a module with a built-in semiconductor in Embodiment 3 of the present invention.

FIGS. 8A to 8E are cross-sectional views showing each process of a method for manufacturing a module with a built-in semiconductor in Embodiment 3 of the present invention.

FIGS. 9A to 9C are cross-sectional views showing a module with a built-in semiconductor in an embodiment of the present invention.

FIGS. 10A and 10B are cross-sectional views showing a module with a built-in semiconductor in an embodiment of the present invention.

FIG. 11 is a cross-sectional view showing a module with a built-in semiconductor in an embodiment of the present invention.

FIG. 12 is a cross-sectional view showing a module with a built-in semiconductor in an embodiment of the present invention.

FIGS. 13A and 13B are cross-sectional views showing a module with a built-in semiconductor in an embodiment of the present invention.

FIG. 14 is a cross-sectional view showing a module with a built-in semiconductor in an embodiment of the present invention.

FIG. 15 is a cross-sectional view showing a module with a built-in semiconductor in an embodiment of the present invention.

### BEST MODE FOR CARRYING OUT THE INVENTION

The module with a built-in semiconductor of the present invention includes a first wiring board, a second wiring board, an interlayer connection member having electrical insulation properties that is located between the first wiring board and the second wiring board, and a semiconductor device contained in the interlayer connection member. The first wiring board includes, e.g., an insulating base material and a first wiring pattern formed on both principal surfaces of the insulating base material. Similarly, the second wiring board includes, e.g., an insulating base material and a second wiring pattern formed on both principal surfaces of the insulating base material.

In the module with a built-in semiconductor of the present invention, the first wiring pattern and the second wiring pattern are connected electrically by a via conductor passing through the interlayer connection member, the back side of the semiconductor device is die-bonded to the first wiring board via an adhesive, and a first electrode pad provided in the circuit surface of the semiconductor device is connected electrically to the second wiring pattern via a protruding electrode. In this configuration, the semiconductor device may be die-bonded to either the insulating base material or the first wiring pattern of the first wiring board. Moreover, the semiconductor device may be formed of a single semiconductor chip or a plurality of semiconductor chips stacked in layers.

In the manufacturing process of the module with a built-in semiconductor of the present invention, the semiconductor device first can be die-bonded to the first wiring board (supporting material) and then flip-chip mounted on the second wiring pattern. Therefore, even if the semiconductor device is thin, it is possible to prevent a crack or failure from occurring during transport of the semiconductor device, formation of the protruding electrode, or sealing of the semiconductor device.

In the module with a built-in semiconductor of the present invention, the semiconductor device may be housed in a cavity provided in the interlayer connection member. This configuration can prevent the via conductor from being deformed due to the flow of the interlayer connection member in the sealing process of the semiconductor device, as will be described later. Therefore, the connection reliability of the via conductor can be improved. The size of the cavity may be determined appropriately in accordance with the size of the semiconductor device to be housed. For example, a gap between the semiconductor device and the inner wall of the cavity may be in the range of 30 μm to 200 μm.

In the module with a built-in semiconductor of the present invention, the first wiring pattern and a second electrode pad provided in the circuit surface of the semiconductor device may be connected electrically. With this configuration, the connection points of the semiconductor device can be divided between the first wiring pattern and the second wiring pattern, thereby reducing the number of lands on the second wiring board and the length of routing of the second wiring pattern. Thus, the module with a built-in semiconductor easily can have a smaller size and higher density. In such a case, the first wiring pattern and the second electrode pad may be connected electrically with a wire. Since the semiconductor device can be mounted using current mounting technology, i.e., wire-bonding mounting and flip-chip mounting, the existing equipment can be used for mounting of the semiconductor device.

In the module with a built-in semiconductor of the present invention, when the first wiring pattern and the second electrode pad are connected electrically with a wire, the wire and the semiconductor device may be sealed with a sealing resin. This configuration can ensure the mounting reliability of the semiconductor device for a long period of time. The sealing resin is not particularly limited as long as it can be used as a material for sealing the semiconductor device, and may be, e.g., a resin composition that includes a thermosetting resin (epoxy resin etc.) as the main component.

In the module with a built-in semiconductor of the present invention, when the first wiring pattern and the second electrode pad are connected electrically with a wire, the wire and the protruding electrode may be made of the same material. If the same material is used for the wire and the protruding electrode, such as a gold wire and a gold bump, they can be formed by the same apparatus, resulting in a less complicated manufacturing process and low cost.

In the module with a built-in semiconductor of the present invention, the interlayer connection member preferably includes an inorganic filler and a thermosetting resin. This configuration can dissipate heat generated from the semiconductor device quickly. Examples of the inorganic filler include Al₂O₃, MgO, BN, AlN, and SiO₂. When the thermosetting resin is an epoxy resin, phenol resin, or cyanate resin, the heat resistance and the electrical insulation properties can be improved. A thermoplastic resin may be used instead of the thermosetting resin.

In the module with a built-in semiconductor of the present invention, the semiconductor device preferably has a thickness of 100 μm or less. In the conventional mounting method, if the thickness of a semiconductor device is 100 μm or less, there are many failures caused by cracks of the semiconductor device during the mounting process. However, such a problem does not occur readily in the configuration of the present invention. In other words, the present invention uses the semiconductor device with a thickness of 100 μm or less, and therefore can provide its function more effectively. Further, the use of the semiconductor device with a thickness of 100 μm or less makes it easier to reduce the thickness of the module with a built-in semiconductor.

In the module with a built-in semiconductor of the present invention, the adhesive preferably includes a resin and a metal filler. When the adhesive includes a metal filler with high thermal conductivity, heat generated from the semiconductor device can be transferred efficiently to the first wiring board and dissipated.

In the module with a built-in semiconductor of the present invention, the first wiring board preferably includes a thermal via directly below a position to which the semiconductor device is die-bonded. With this configuration, heat generated from the semiconductor device can be dissipated via the thermal via.

The module with a built-in semiconductor of the present invention may includes a plurality of at least one of the first wiring boards and the second wiring board, a plurality of the interlayer connection members, and a plurality of the semiconductor devices. The wiring boards and the interlayer connection members may be stacked in multiple levels to form a multilayer structure, and at least one semiconductor device may be contained in each of the interlayer connection members. This configuration easily can provide a three-dimensional arrangement or interconnection of the semiconductor devices, thus achieving high density mounting.

A method for manufacturing a module with a built-in semiconductor of the present invention includes the following steps of: a) die-bonding the back side of a semiconductor device to a desired position of a first wiring board via an adhesive; b) forming a protruding electrode on a first electrode pad provided in the circuit surface of the semiconductor device so as to be connected electrically to a second wiring pattern formed on a second wiring board; c) forming a through hole in an interlayer connection member in the uncured state and filling the through hole with a conductive paste; d) aligning and stacking the first wiring board, the interlayer connection member, and the second wiring board so that the semiconductor device is flip-chip mounted on the second wiring pattern, and the through hole is arranged between a first wiring pattern formed on the first wiring board and the second wiring pattern; and e) heating and pressing the first wiring board, the interlayer connection member, and the second wiring board thus stacked so that the semiconductor device is contained in the interlayer connection member, the first wiring board, the interlayer connection member, and the second wiring board are cured and formed integrally, and the first wiring pattern and the second wiring pattern are connected electrically by a via conductor formed in the through hole.

In the manufacturing method of the present invention, the semiconductor device first can be die-bonded to the first wiring board (supporting material) and then flip-chip mounted on the second wiring pattern. Therefore, even if the semiconductor device is thin, it is possible to prevent a crack or failure from occurring during the manufacturing process.

The manufacturing method of the present invention further may include a step of electrically connecting the first wiring pattern and a second electrode pad provided in the circuit surface of the semiconductor device with a wire, the step being performed after the step a) and before the step d). With this method, the connection points of the semiconductor device can be divided between the first wiring pattern and the second wiring pattern, thereby reducing the number of lands on the second wiring board and the length of routing of the second wiring pattern. Thus, the module with a built-in semiconductor easily can have a smaller size and higher density.

The manufacturing method of the present invention further may include a step of polishing the back side of the semiconductor device before the step a). With this method, the thickness of the semiconductor device to be mounted can be adjusted freely, so that the thickness of the module with a built-in semiconductor can be reduced.

In the step c) of the manufacturing method of the present invention, a cavity for housing the semiconductor device may be provided in the interlayer connection member. This method can prevent the via conductor from being deformed due to the flow of the interlayer connection member in the sealing process of the semiconductor device. Therefore, the connection reliability of the via conductor can be improved.

In the step d) of the manufacturing method of the present invention, a resin material may be arranged in an electrical connection portion of the semiconductor device. Since the electrical connection portion is sealed with the resin material, this method can ensure the mounting reliability of the semiconductor device for a long period of time.

In the step e) of the manufacturing method of the present invention, the semiconductor device may be heated at a temperature not more than a curing temperature of the interlayer connection member when the semiconductor device is contained in the interlayer connection member. With this method, the semiconductor device is contained before curing the interlayer connection member, and it is possible to minimize a stress imposed on the semiconductor device by the pressure during sealing. Thus, the method is effective particularly in embedding the semiconductor device in the interlayer connection member.

Hereinafter, embodiments of the present invention will be described with reference to the drawings. For the sake of simplicity, the components having substantially the same function are denoted by the same reference numerals in the drawings. The present invention is not limited to the following embodiments.

### Embodiment 1

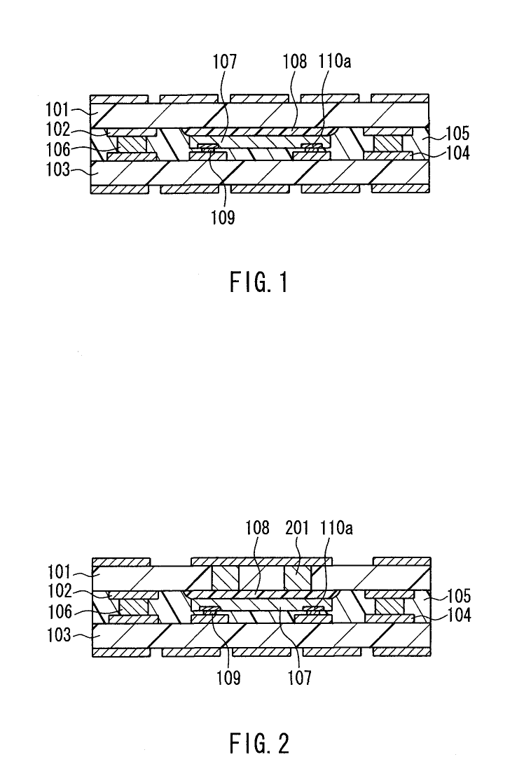

FIG. 1 is a cross-sectional view schematically showing the configuration of a module with a built-in semiconductor in Embodiment 1. In FIG. 1, reference numeral 101 is a first wiring board; 102 is a first wiring pattern formed on the first wiring board 101; 103 is a second wiring board; 104 is a second wiring pattern formed on the second wiring board 103; 105 is an interlayer connection member for joining the first wiring board 101 and the second wiring board 103 while providing electrical insulation between them; 106 is a via conductor for electrically connecting the necessary portions of the first wiring pattern 102 and the second wiring pattern 104; 107 is a semiconductor device that is sealed in the interlayer connection member 105 between the first wiring board 101 and the second wiring board 103; 108 is an adhesive that is applied for die bonding of the semiconductor device 107 to the first wiring board 101; and 109 is a protruding electrode for electrically connecting a first electrode pad 110a provided in the die-bonded semiconductor device 107 and the second wiring pattern 104. With this configuration, the semiconductor device 107 is flip-chip mounted on the second wiring pattern 104 via the protruding electrode 109. The protruding electrode 109 may be, e.g., a metal bump of gold or the like. Moreover, a two-stage protruding bump formed by wire bonding, a gold-plated bump, or a bump formed by printing also can be used as the protruding electrode 109.

In the module with a built-in semiconductor of Embodiment 1, the semiconductor device 107 is sealed in the interlayer connection member 105, the back side of the semiconductor device 107 is die-bonded to the first wiring board 101 via the adhesive 108, and the semiconductor device 107 is connected electrically to the second wiring board 103. With this configuration, the semiconductor device 107 first can be die-bonded to the first wiring board 101 (supporting material) and then flip-chip mounted on the second wiring pattern 104. Therefore, even if the semiconductor device 107 is thin, it is possible to prevent a crack or failure from occurring during transport of the semiconductor device 107, formation of the protruding electrode 109, or sealing of the semiconductor device 107. Moreover, since the semiconductor device 107 is bonded to the surface of the first wiring board 101, the thermal conductivity can be improved between them.

In this embodiment, each of the first and second wiring boards 101, 103 includes an insulating base material and a wiring pattern formed on both principal surfaces of the insulting base material. The insulating base material is not particularly limited and may be a known material such as a ceramic material or organic material. For example, when the insulating base material is a ceramic material, alumina or sapphire can be used. In the case of an organic material, a resin-containing material, e.g., a hardened material of prepreg that includes a mixture of an inorganic filler and a thermosetting resin can be used. The hardened material of prepreg is particularly preferred because it has good thermal conductivity and can dissipate heat generated during the mounting of components quickly. Moreover, a multilayer wiring board may be used as the first and second wiring boards 101, 103. In such a case, the layers of the multilayer wiring board may be connected electrically by a through hole conductor or inner via.

The first and second wiring patterns 102, 104 are formed by patterning, e.g., a copper foil and have a thickness of about 1 to 50 μm. These wiring patterns may be surface-treated as needed. Examples of the surface treatment include roughening, blackening, nickel plating, and gold plating.

In this embodiment, the interlayer connection member 105 is made of a resin-containing material. For example, a sheet-like composite material including a thermosetting resin and an inorganic filler can be used as the interlayer connection member 105. The interlayer connection member 105 also may consist of a thermosetting resin substantially without using an inorganic filler. The thermosetting resin is not particularly limited as long as it has sufficient electric characteristics, heat resistance, and mechanical strength as an insulating material, and may be an epoxy resin. Examples of the inorganic filler to be added include Al₂O₃, MgO, BN, AlN, and SiO₂. The addition of the inorganic filler can dissipate heat generated from the semiconductor device 107 quickly. When the inorganic filler is BN, the interlayer connection member 105 can have high thermal conductivity and a small thermal expansion coefficient. When the inorganic filler is SiO₂, both the dielectric constant and the specific gravity can be reduced, so that it is useful for high-frequency applications such as a portable telephone. Moreover, when the inorganic filler is amorphous SiO₂, the thermal expansion coefficient of the interlayer connection member 105 becomes closer to that of a silicon semiconductor. It is also possible to add a coupling agent, dispersant, colorant, or release agent to the interlayer connection member 105.

The via conductor 106 passing through the interlayer connection member 105 may be formed in such a manner that a though hole is provided in the interlayer connection member 105 by punching and then filled with a conductive paste, in which a silver filler is dispersed in an epoxy resin material, by printing. The through hole may be formed by known techniques such as drilling, sandblasting, and laser irradiation using a carbon dioxide gas laser or YAG laser. Alternatively, a conductor portion may be formed inside the through hole by plating, thus forming the via conductor 106.

As the semiconductor device 107, not only a silicon semiconductor such as a power device, bipolar device, or MOS (metal oxide semiconductor) device, but also a silicon-germanium semiconductor device or gallium arsenide semiconductor device having low mechanical strength can be used. When the surface of the second wiring pattern 104 connected to the semiconductor device 107 is plated with nickel or gold, the reliability of the electrical connection between the second wiring pattern 104 and the protruding electrode 109 on the semiconductor device 107 can be improved.

FIG. 2 is a cross-sectional view showing a modified module with a built-in semiconductor in Embodiment 1. In the module of FIG. 2, a thermal via 201 for dissipating heat generated from the semiconductor device 107 is formed in the first wiring board 101 directly below the surface to which the semiconductor device 107 is die-bonded. Therefore, the heat generated from the semiconductor device 107 can be dissipated more efficiently. The thermal via 201 may be, e.g., a via conductor made of a conductive paste including a metal filler and a thermosetting resin or via conductor filled in the through hole by plating.

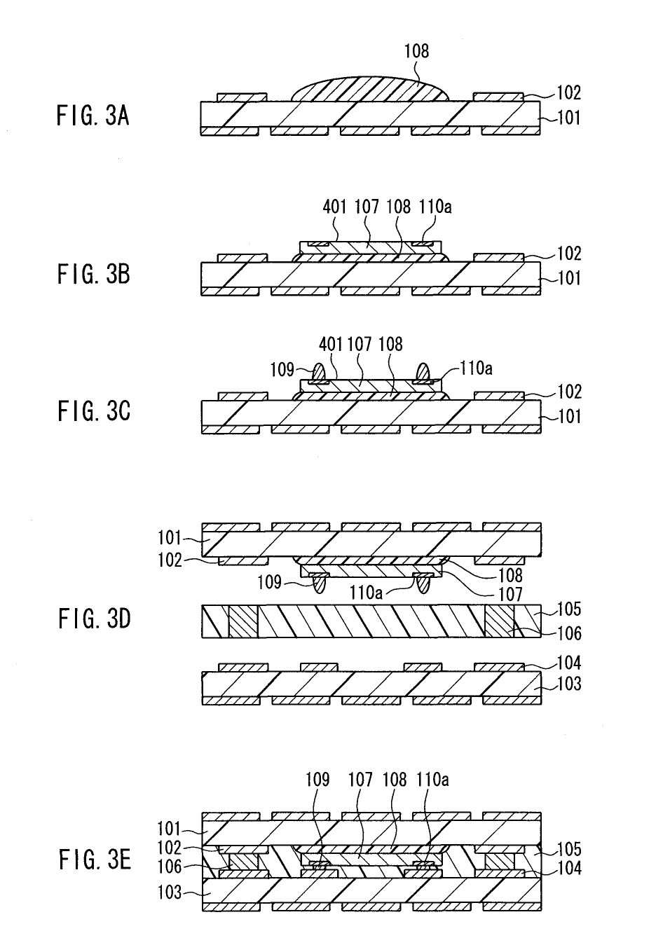

FIGS. 3A to 3E are cross-sectional views showing each process of a method for manufacturing a module with a built-in semiconductor in Embodiment 1.

First, as shown in FIG. 3A, the first wiring board 101 is prepared. The wiring pattern 102 is formed on both principal surfaces of the first wiring board 101. The adhesive 108 is applied to a desired position on the first wiring board 101. As the adhesive 108, e.g., a conductive adhesive obtained by dispersing gold, silver, copper, or silver-palladium alloy in a thermosetting resin or thermoplastic resin can be used. The adhesive 108 may be either a paste material or semi-cured sheet material.

Next, as shown in FIG. 3B, the semiconductor device 107 is mounted on the adhesive 108 applied to the first wiring board 101 with its circuit surface 401 facing upward, and then is heated to cure the adhesive 108, so that the semiconductor device 107 and the first wiring board 101 are bonded together.

Subsequently, as shown in FIG. 3C, the protruding electrode 109 is formed on the first electrode pad 110a provided in the circuit surface 401 of the semiconductor device 107. As the protruding electrode 109, e.g., a gold bump, a two-stage protruding bump formed by wire bonding, a gold-plated bump, or a bump formed by printing can be used.

Next, as shown in FIG. 3D, the second wiring board 103 having the second wiring pattern 104 on both principal surfaces and the interlayer connection member 105 having the via conductors 106 for connecting the first wiring pattern 102 and the second wiring pattern 104 are prepared. Then, the first wiring board 101, the interlayer connection member 105, and the second wiring board 103 are aligned and stacked.

By heating and pressing the first wiring board 101, the interlayer connection member 105, and the second wiring board 103, as shown in FIG. 3E, the interlayer connection member 105 is cured, the semiconductor device 107 and the second wiring pattern 104 are connected electrically via the protruding electrode 109, and the first wiring pattern 102 and the second wiring pattern 104 are connected electrically by the via conductors 106 and thus integrated with each other. This manufacturing method can facilitate the production of the module with a built-in semiconductor in Embodiment 1. A plurality of interlayer connection members 105 having the via conductors 106 and a plurality of wiring boards including desired wiring patterns may be used and stacked repeatedly in the above manner, thus producing a multilayer module with a built-in semiconductor.

### Embodiment 2

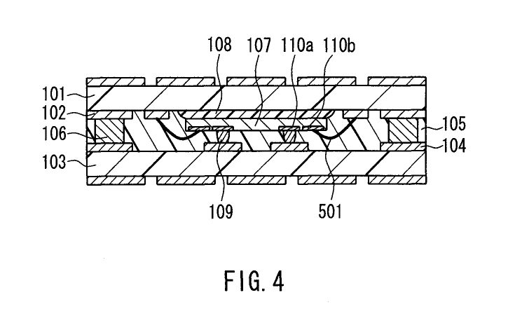

FIG. 4 is a cross-sectional view showing a module with a built-in semiconductor in Embodiment 2 of the preset invention. In the module of FIG. 4, a second electrode pad 110b provided in the semiconductor device 107 and the first wiring pattern 102 are connected electrically with a wire 501. With this configuration, the connection points of the semiconductor device 107 can be divided between the first wiring pattern 102 and the second wiring pattern 104, thereby reducing the number of lands on the second wiring board 103 and the length of routing of the second wiring pattern 104. Thus, the module with a built-in semiconductor easily can have a smaller size and higher density. The other aspects are the same as those of the module (FIG. 1) in Embodiment 1.

In this embodiment, when the protruding electrode 109 is, e.g., a two-stage protruding bump formed by wire bonding, and the wire 501 is made of the same material as the two-stage protruding bump, mounting of the semiconductor device 107 can be performed in the same process, thus eliminating the need for any complicated process.

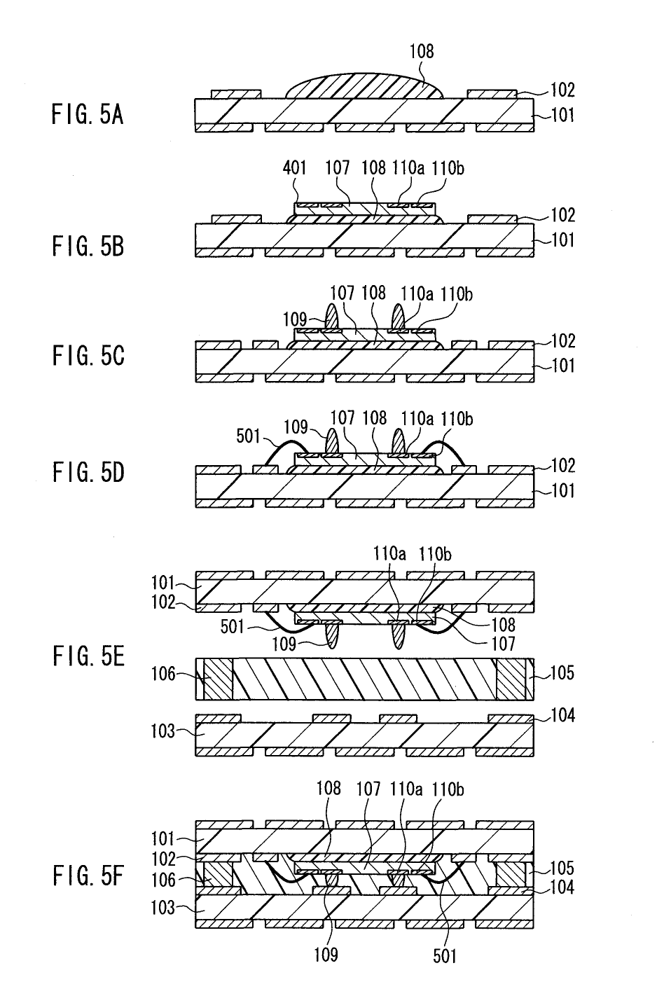

FIGS. 5A to 5F are cross-sectional views showing each process of a method for manufacturing a module with a built-in semiconductor in Embodiment 2. First, as shown in FIGS. 5A and 5B, the semiconductor device 107 is die-bonded to a desired position on the first wiring board 101 via the adhesive 108. These processes are the same as those in FIGS. 3A and 3B.

Next, as shown in FIG. 5C, the protruding electrode 109 is formed on the first electrode pad 110a provided in the semiconductor device 107.

Subsequently, as shown in FIG. 5D, the second electrode pad 110b provided in the semiconductor device 107 and the first wiring pattern 102 are connected electrically with the wire 501.

Next, as shown in FIG. 5E, the second wiring board 103 having the second wiring pattern 104 on both principal surfaces and the interlayer connection member 105 having the via conductors 106 for connecting the first wiring pattern 102 and the second wiring pattern 104 are prepared. Then, the first wiring board 101, the interlayer connection member 105, and the second wiring board 103 are aligned and stacked.

By heating and pressing the first wiring board 101, the interlayer connection member 105, and the second wiring board 103, as shown in FIG. 5F, the interlayer connection member 105 is cured, the semiconductor device 107 and the second wiring pattern 104 are connected electrically via the protruding electrode 109, and the first wiring pattern 102 and the second wiring pattern 104 are connected electrically by the via conductors 106 and thus integrated with each other. This manufacturing method can facilitate the production of the module with a built-in semiconductor in Embodiment 2.

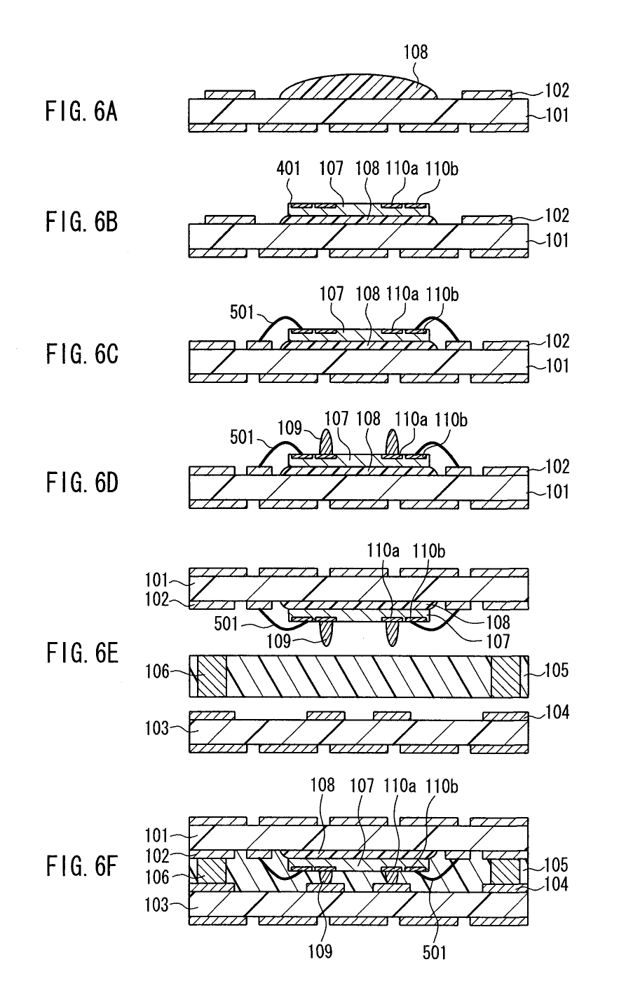

FIGS. 6A to 6F are cross-sectional views showing each process of another method for manufacturing a module with a built-in semiconductor in Embodiment 2. As shown in FIGS. 6A and 6B, the semiconductor device 107 is die-bonded to a desired position on the first wiring board 101 via the adhesive 108. These processes are the same as those in FIGS. 3A and 3B.

Next, as shown in FIG. 6C, the second electrode pad 110b provided in the semiconductor device 107 and the first wiring pattern 102 are connected electrically with the wire 501.

Subsequently, as shown in FIG. 6D, the protruding electrode 109 is formed on the first electrode pad 110a provided in the semiconductor device 107.

Next, as shown in FIG. 6E, the second wiring board 103 having the second wiring pattern 104 on both principal surfaces and the interlayer connection member 105 having the via conductors 106 for connecting the first wiring pattern 102 and the second wiring pattern 104 are prepared. Then, the first wiring board 101, the interlayer connection member 105, and the second wiring board 103 are aligned and stacked.

By heating and pressing the first wiring board 101, the interlayer connection member 105, and the second wiring board 103, as shown in FIG. 6F, the interlayer connection member 105 is cured, the semiconductor device 107 and the second wiring pattern 104 are connected electrically via the protruding electrode 109, and the first wiring pattern 102 and the second wiring pattern 104 are connected electrically by the via conductors 106 and thus integrated with each other. This manufacturing method can facilitate the production of the module with a built-in semiconductor in Embodiment 2.

### Embodiment 3

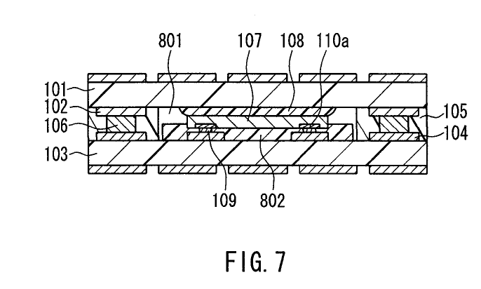

FIG. 7 is a cross-sectional view showing a module with a built-in semiconductor in Embodiment 3. In the module of FIG. 7, a cavity 801 for housing the semiconductor device 107 is provided in the interlayer connection member 105. The back side of the semiconductor device 107 is die-bonded to the first wiring board 101 via the adhesive 108, and the semiconductor device 107 and the second wiring pattern 104 are connected electrically via the protruding electrode 109. Moreover, a region where the protruding electrode 109 and the second wiring board 103 are connected electrically is sealed with a resin material 802. As the resin material 802, e.g., an insulating resin material obtained by kneading a thermosetting resin or thermoplastic resin and an inorganic filler can be used. The cavity 801 may be formed by known techniques such as drilling, punching, sandblasting, and laser irradiation using a carbon dioxide gas laser or YAG laser.

In this embodiment, since the semiconductor device 107 is housed in the cavity 801, it is possible to prevent the via conductor 106 from being deformed due to the flow of the interlayer connection member 105 in the sealing process of the semiconductor device 107. Therefore, the connection reliability of the via conductor 106 can be improved. Moreover, since the electrical connection portion of the semiconductor device 107 is sealed with the resin material 802, the mounting reliability can be improved.

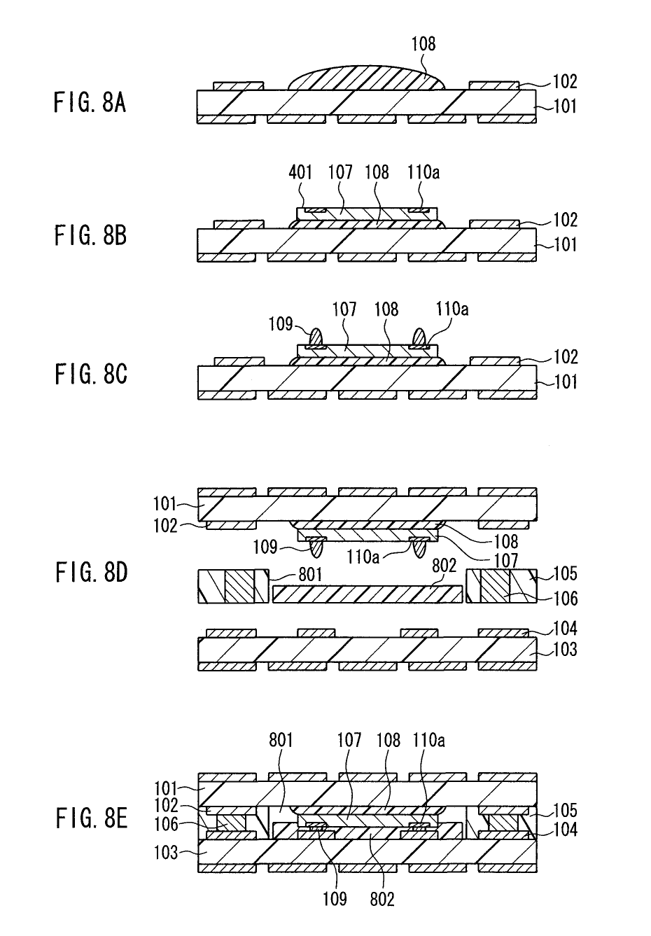

FIGS. 8A to 8E are cross-sectional views showing each process of a method for manufacturing a module with a built-in semiconductor in Embodiment 3. As shown in FIGS. 8A and 8B, the semiconductor device 107 is die-bonded to a desired position on the first wiring board 101 via the adhesive 108. Subsequently, as shown in FIG. 8C, the protruding electrode 109 is formed on the first electrode pad 110a provided in the semiconductor device 107. These processes are the same as those in FIGS. 3A to 3C.

Next, as shown in FIG. 8D, the second wiring board 103 having the second wiring pattern 104 on both principal surfaces, the resin material 802 for sealing a region where the second wiring pattern 104 and the protruding electrode 109 are connected electrically, and the interlayer connection member 105 that has the via conductors 106 for connecting the first wiring pattern 102 and the second wiring pattern 104 and includes the cavity 801 for housing the die-bonded semiconductor device 107 are prepared. Then, the first wiring board 101, the interlayer connection member 105, the resin material 802, and the second wiring board 103 are aligned and stacked. In FIG. 8D, although the resin material 802 is a semi-cured sheet material, a paste material also can be used.

By heating and pressing the first wiring board 101, the interlayer connection member 105, the resin material 802, and the second wiring board 103, as shown in FIG. 8E, the interlayer connection member 105 is cured, the semiconductor device 107 and the second wiring pattern 104 are connected electrically via the protruding electrode 109, and the first wiring pattern 102 and the second wiring pattern 104 are connected electrically by the via conductors 106 and thus integrated with each other. This manufacturing method can facilitate the production of the module with a built-in semiconductor in Embodiment 3.

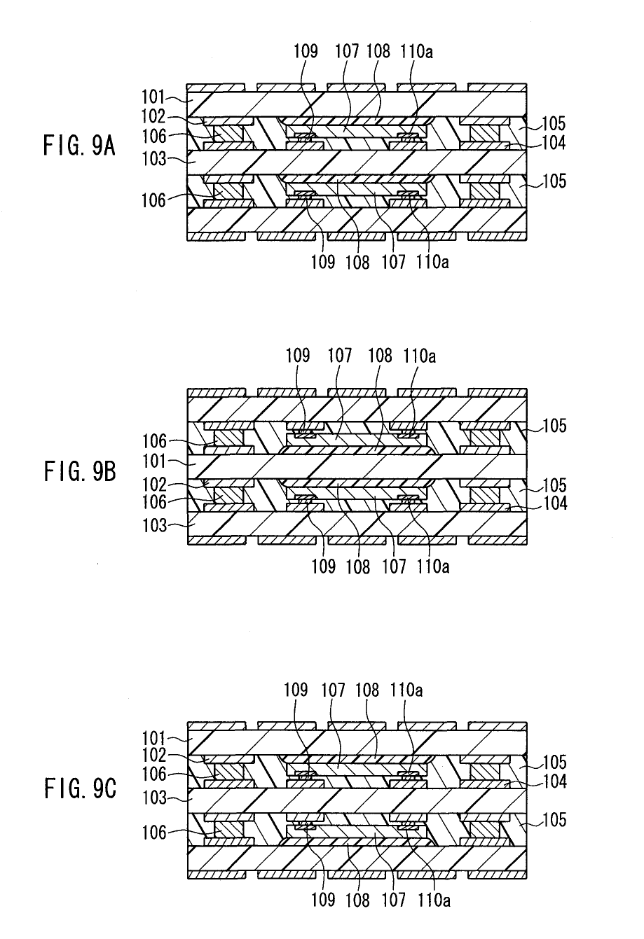

The embodiments of the present invention have been described, but the present invention is not limited to the above embodiments. For example, as shown in FIGS. 9A to 9C, a six-layer multilayer substrate having six-layer wiring patterns may be used, and the semiconductor device 107 may be contained in each of the interlayer connection members 105 separated into two levels. In this configuration, one of the semiconductor devices 107 can be a semiconductor memory, and the other can be LSI (large scale integration), thereby containing different types of the semiconductor devices 107. Moreover, the same type of the semiconductor devices 107 can be contained as well. In this case, the LSI may be, e.g., a logic LSI.

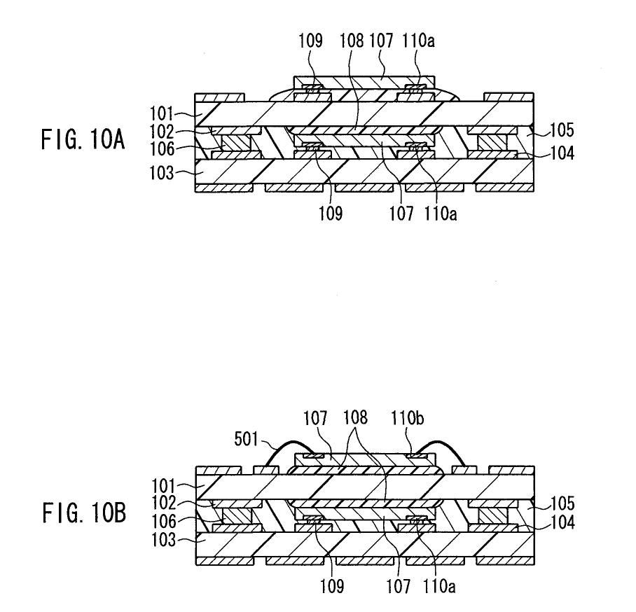

As shown in FIGS. 10A and 10B, another semiconductor device 107 may be mounted on the surface of the wiring board by flip-chip mounting or wire-bonding mounting.

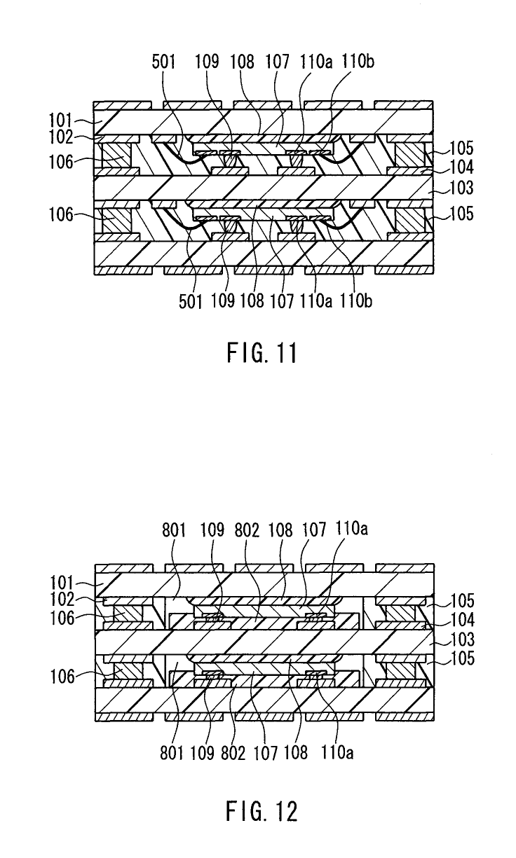

As shown in FIG. 11, which is a modified example of FIG. 9A, each of the semiconductor devices 107 may be mounted by flip-chip mounting and wire-bonding mounting. As shown in FIG. 12, which is a modified example of FIG. 9A, the cavity 801 and the resin material 802 may be used in the module with a built-in semiconductor.

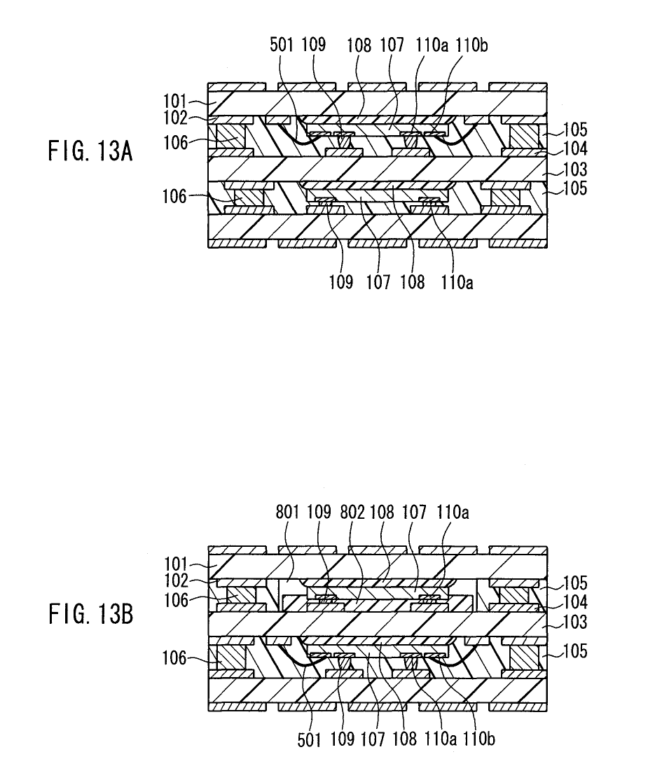

As shown in FIG. 13A, which is a modified example of FIG. 11, one of the semiconductor devices 107 may be mounted by flip-chip mounting and wire-bonding mounting, and the other may be mounted by flip-chip mounting. As shown in FIG. 13B, which is a modified example of FIG. 13A, the semiconductor device 107 mounted by flip-chip mounting may be housed in the cavity 801, and the electrical connection portion of this semiconductor device 107 may be sealed with the resin material 802.

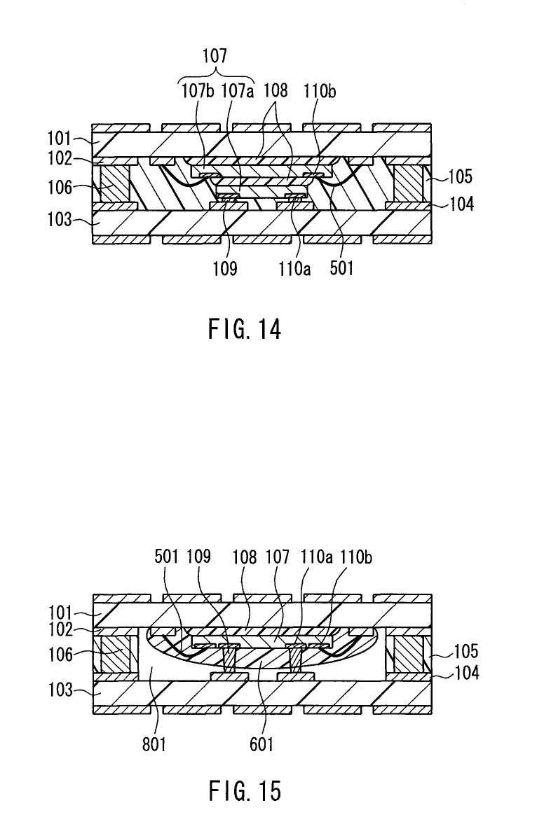

As shown in FIG. 14, the semiconductor device 107 may be formed by stacking a semiconductor chip 107a and a semiconductor chip 107b. As shown in FIG. 15, the first wiring pattern 102 and the second electrode pad 110b may be connected electrically with the wire 501, and the semiconductor device 107 and the wire 501 may be sealed with a sealing resin 601. The configuration of FIG. 15 can ensure the mounting reliability of the semiconductor device 107 for a long period of time.

Hereinafter, the present invention will be described in detail by way of an example. The present invention is not limited to the following example.

In this example, the module with a built-in semiconductor of Embodiment 1 was produced by the method as shown in FIGS. 3A to 3E. The materials used are described below.

The first wiring board 101 and the second wiring board 103 were a prepreg (EL-114 with a thickness of 140 μm produced by Shin-Kobe Electric Machinery Co., Ltd.) obtained by impregnating an aramid nonwoven fabric with an epoxy resin. The adhesive 108 was an adhesive (DBC120SL produced by Panasonic Factory Solutions Co., Ltd.) obtained by dispersing a silver filler in a bisphenol F liquid epoxy resin. The semiconductor device 107 was a silicon memory semiconductor (10 mm square, thickness: 100 μm). The protruding electrode 109 was formed using a gold wire with a diameter of 25 μm (produced by Mitsubishi Materials Corporation). As the interlayer connection member 105, 90 mass % of spherical Al₂O₃ (AS-40 with a diameter of 12 μm produced by Showa Denko K.K.), 9.5 mass % of liquid epoxy resin (EF-450 produced by Sanyu Rec Co., Ltd.), and 0.5 mass % of titanate coupling agent (46B produced by Ajinomoto Co., Inc.) were kneaded and formed into a film with a thickness of 150 μm. As the via conductor 106, 85 mass % of spherical copper particles, 3 mass % of bisphenol A epoxy resin (EPIKOTE 828 produced by Japan Epoxy Resins Co., Ltd.), 9 mass % of glycidyl ester epoxy resin (YD-171 produced by Tohto Kasei Co., Ltd.), and 3 mass % of amine adduct curing agent (MY-24 produced by Ajinomoto Co., Inc.) were kneaded into a paste. In the process of FIG. 3B, the adhesive 108 was cured by heating at 180° C. for 3 minutes. In the process of FIG. 3E, the layers were integrated with each other by heating and pressing them at 5 Mpa and 170° C. for 60 minutes.

The mounting reliability of the module with a built-in semiconductor of the above example was evaluated by conducing a solder reflow test and a temperature cycling test. In the solder reflow test, the module of the example ran through 10 times a belt-type reflow testing machine at a maximum temperature of 260° C. for a treatment time of 10 seconds. In the temperature cycling test, the higher temperature was set to 125° C. and the lower temperature was set to −60° C., and the module of the example was maintained at each of the temperatures for 30 minutes and subjected to 200 cycles. In either case, the module of the example after each test did not cause a crack, and no particular anomalies were detected even by an ultrasonic test. These results confirmed that the module with a built-in semiconductor of the present invention had high mounting reliability. Moreover, there was almost no difference in connection resistance of the via conductor 106 formed in the interlayer connection member 105 between before and after the test.

### INDUSTRIAL APPLICABILITY

The present invention can provide a module with a built-in semiconductor having high mounting reliability, even if a thin semiconductor device is used.

1. A module with a built-in semiconductor comprising:
a first wiring board;
a second wiring board;
an interlayer connection member having electrical insulation properties that is located between the first wiring board and the second wiring board; and
a semiconductor device contained in the interlayer connection member,
wherein the first wiring board comprises a first wiring pattern formed on both principal surfaces,
the second wiring board comprises a second wiring pattern formed on both principal surfaces, the first wiring pattern and the second wiring pattern are connected electrically by a via conductor passing through the interlayer connection member, and
a back side of the semiconductor device is die-bonded to the first wiring board via an adhesive, and a first electrode pad provided in a circuit surface of the semiconductor device is connected electrically to the second wiring pattern via a protruding electrode.

2. The module according to claim 1, wherein the semiconductor device is housed in a cavity provided in the interlayer connection member.

3. The module according to claim 1, wherein the semiconductor device is formed of a plurality of semiconductor chips stacked in layers.

4. The module according to claim 1, wherein the first wiring pattern and a second electrode pad provided in the circuit surface of the semiconductor device are connected electrically.

5. The module according to claim 4, wherein the first wiring pattern and the second electrode pad are connected electrically with a wire.

6. The module according to claim 1, wherein the first wiring pattern and a second electrode pad provided in the circuit surface of the semiconductor device are connected electrically with a wire, and
the wire and the semiconductor device are sealed with a sealing resin.

7. The module according to claim 1, wherein the first wiring pattern and a second electrode pad provided in the circuit surface of the semiconductor device are connected electrically with a wire, and
the wire and the protruding electrode are made of the same material.

8. The module according to claim 1, wherein the interlayer connection member comprises an inorganic filler and a thermosetting resin.

9. The module according to claim 1, wherein the semiconductor device has a thickness of 100 μm or less.

10. The module according to claim 1, wherein the adhesive comprises a resin and a metal filler.

11. The module according to claim 1, wherein the first wiring board further comprises a thermal via directly below a position to which the semiconductor device is die-bonded.

12. The module according to claim 1, comprising:
a plurality of at least one of the first wiring boards and the second wiring boards;
a plurality of the interlayer connection members; and
a plurality of the semiconductor devices,
wherein the wiring boards and the interlayer connection members are stacked in multiple levels to form a multilayer structure, and
at least one semiconductor device is contained in each of the interlayer connection members.

13. A method for manufacturing a module with a built-in semiconductor containing a semiconductor device comprising steps of:
a) die-bonding a back side of the semiconductor device to a desired position of a first wiring board via an adhesive;
b) forming a protruding electrode on a first electrode pad provided in a circuit surface of the semiconductor device so as to be connected electrically to a second wiring pattern formed on a second wiring board;
c) forming a through hole in an interlayer connection member in an uncured state and filling the through hole with a conductive paste;
d) aligning and stacking the first wiring board, the interlayer connection member, and the second wiring board so that the semiconductor device is flip-chip mounted on the second wiring pattern, and the through hole is arranged between a first wiring pattern formed on the first wiring board and the second wiring pattern; and
e) heating and pressing the first wiring board, the interlayer connection member, and the second wiring board thus stacked so that the semiconductor device is contained in the interlayer connection member, the first wiring board, the interlayer connection member, and the second wiring board are cured and formed integrally, and the first wiring pattern and the second wiring pattern are connected electrically by a via conductor formed in the through hole.

14. The method according to claim 13, further comprising a step of electrically connecting the first wiring pattern and a second electrode pad provided in the circuit surface of the semiconductor device with a wire, the step being performed after the step a) and before the step d).

15. The method according to claim 13, further comprising a step of polishing the back side of the semiconductor device before the step a).

16. The method according to claim 13, wherein in the step c), a cavity for housing the semiconductor device is provided in the interlayer connection member.

17. The method according to claim 13, wherein in the step d), a resin material is arranged in an electrical connection portion of the semiconductor device.

18. The method according to claim 13, wherein in the step e), the semiconductor device is heated at a temperature not more than a curing temperature of the interlayer connection member when the semiconductor device is contained in the interlayer connection member.
